(19) United States
(12) Patent Application Publication
(10) Pub. No.: US 2022/0349958 A1
(43) Pub. Date: Nov. 3, 2022

(54) WORKING STATE DETERMINATION OF ELECTRONIC COMPONENTS

(71) Applicant: Hewlett-Packard Development Company, L.P., Spring, TX (US)

(72) Inventors: Chih-Hung Chien, Taipei City (TW); Shih Huang Wu, Spring, TX (US); Po Chao Chen, Taipei City (TW)

(73) Assignee: Hewlett-Packard Development Company, L.P., Spring, TX (US)

(21) Appl. No.: 17/298,564

(22) PCT Filed: May 29, 2019
(86) PCT No.: PCT/US2019/034261

§ 371 Date: May 29, 2021

(51) Int. Cl. G01R 31/68

(52) U.S. Cl. CPC G01R 31/68

(57) ABSTRACT

Techniques for determining a working state of an electronic component of an electronic device are described. The electronic component is coupled to the electronic device via a connection interface and a connector. The electronic device further comprises a contact detection assembly. The contact detection assembly detects a position of the connector relative to a connection interface. Based on the position of the connector relative to the connection interface, a state of connection between the connector and the connection interface is determined.

### BACKGROUND

Electronic devices are made up of multiple electronic components that are assembled together to perform various predefined functions. The electronic components are further electrically coupled to one another to allow interoperability. For instance, in an access point assembly, a module may be electrically coupled to various antennas, where the module may use the antennas to transmit/receive electromagnetic signals of various frequencies.

### BRIEF DESCRIPTION OF DRAWINGS

FIG. 1 illustrates various components of a connection assembly, in accordance with an example of the present subject matter,

FIG. 2(a) illustrates a top-view of a connection assembly, in accordance with an example of the present subject matter,

FIG. 2(b) illustrates a side-view of a connection assembly, ire accordance with an example of the present subject matter,

FIG. 2(c) illustrates a side-view of a connection assembly, in accordance with another example of the present subject matter,

FIG. 3(a) illustrates an electronic device with a contact detection assembly, in accordance with an example of the present subject matter,

FIG. 3(b) illustrates an electronic device with a contact detection assembly, in accordance with another example of the present subject matter, and

FIG. 4 illustrates a method for detecting a working state of a plurality of antennas in an electronic device, in accordance with an example of the present subject matter.

### DETAILED DESCRIPTION

In electronic devices, many electronic components are coupled to one another either through wired or wireless couplings. To facilitate coupling of electronic components, electronic devices have connection interfaces which are utilized as connection points for connectors of the electronic components. Upon assembly of different electronic components within the electronic devices, connections of the electronic components are tested to detect the presence of any faults in couplings and check adequate working of the electronic components.

Testing of electronic components, such as antennas generally involve utilization of testing equipment that exchanges and analyses test signals between the electronic components of the electronic device. For instance, test signals may be generated and exchanged between the antennas of the electronic device, and thereafter analysed based on predetermined output quality. If the quality of the output is found to be equivalent to the predetermined output quality, the working of electronic component is determined to be satisfactory. However, if the quality of output is found to be less than the predetermined output quality, the working of the electronic component is determined to be unsatisfactory.

Unsatisfactory working of electronic components may occur due to various reasons, such as utilization of incorrect testing techniques, defective electronic components, and improper coupling of connectors of the electronic components with connection interfaces. In situations where the working of the electronic components is determined to be unsatisfactory, generally re-testing is undertaken and fault detection procedures are employed. While utilization of testing equipment for examination of electronic components is expensive, implementing fault detection procedures is further time consuming and resource intensive.

According to an example implementation of the present subject matter, techniques of determining a working state of an electronic component of an electronic device are described. The described techniques allow determination of a state of a connection between the electronic component and the electronic device to allow determination of improper coupling of connectors of the electronic components with connection interfaces. Based on the determination of the state of connection between the electronic component and the electronic device, the working state of the electronic component is determined.

In an example, an electronic device includes various electronic components where each of the electronic component is coupled to the electronic device through a connection assembly. The connection assembly may include a connection interface of the electronic device, connected to a connector of the electronic component. In an example of the present subject matter, the connection assembly further includes a contact detection assembly. The contact detection assembly detects the state of connection between the connector and the connection interface to determine whether the connection of the electronic device with the electronic component is adequate for the functioning of the electronic component.

According to an example of the present subject matter, the contact detection assembly detects a position of the connector relative to the connection interface to determine a state of the connection. For example, the contact detection assembly may include a detection pin to determine a relative position of the connector relative to the connection interface. Based on the position of the detection pin, the contact detection assembly may determine the state of the connection between the connector and the connection interface.

Therefore, the state of working of the electronic components, such as an antenna, is determined based on the state of the connection between the connector and the connection interface. This, in turn, facilitates in troubleshooting of the electronic devices without implementation of expensive testing equipment and fault detection procedures. Thus, the time and resource consumption associated with testing and fault detection procedures of the electronic components is avoided.

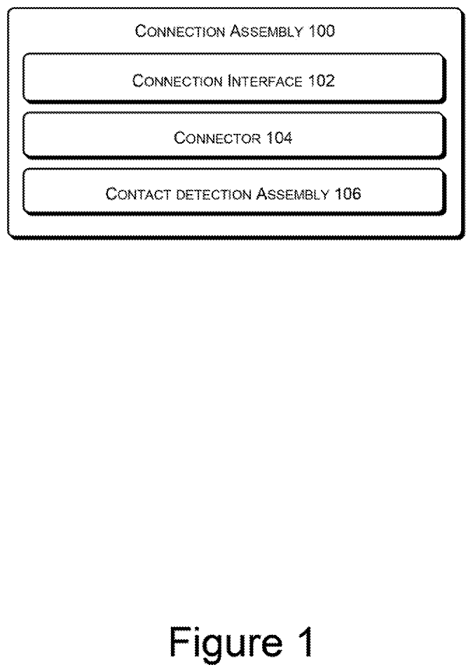

The above techniques are further described with reference to FIG. 1 to FIG. 4. It should be noted that the description and the figures merely illustrate the principles of the present subject matter along with examples described herein and should not be construed as a limitation to the present subject matter. It is, thus understood that various arrangements may be devised that although not explicitly described or shown herein, embody the principles of the present subject matter. Moreover, all statements herein reciting principles, aspects, and implementations of the present subject matter, as well as specific examples thereof, are intended to encompass equivalents thereof.

FIG. 1 illustrates various components of a connection assembly 100 of an electronic device, in accordance with an example implementation of the present subject matter. The connection assembly 100 includes a connection interface 102, a connector 104, and a contact detection assembly 106. In an example, the connection interface 102 couples the electronic device to an electronic component, such as an antenna, via the connector 104. Examples of connection interface 102 may include, but not limited to, RJ45 interface, coaxial socket, universal serial bus (USB) interface, high definition multimedia interface (HDMI) and video graphics array (VGA) interface.

The electronic component may be coupled to the electronic device either through wired or wireless connection. In an example, the antenna may be coupled to the electronic device by wired connection and the connector may be a cable connector. That is, the electronic component includes a cable such that the cable has a connector 104 to couple to the connection interface 102.

While the aforementioned example describes the coupling between the electronic device and the electronic components using a cable connector, it would be noted that wireless radio frequency (RE) connectors may also be used to couple the electronic components to the electronic device.

Examples of the cable connector may include, but not limited to, Bayonet Neill—Concelman (BNC) connector, Sub Miniature Version A (SMA) connector, Sub Miniature Version B (SMB) connector, Threaded Neill—Concelman (TNC) connector, and micro coaxial connector (MCX) connector.

In an example implementation of the present subject matter, the contact detection assembly 106 may detect the state of the connection between the connector 104 and the connection interface 102. In an example, the contact detection assembly 106 detects the state of the connection between the connector 104 and the connection interface 102 based on a position of the connector 104 relative to the connection interface 102. Further, based on the state of the connection between the connector 104 and the connection interface 102, a working state of the electronic component is determined. The manner in which the state of the connection between the connector 104 and the connection interface 102 is determined to determine the working state of the electronic component is described in detail with respect to the forthcoming figures.

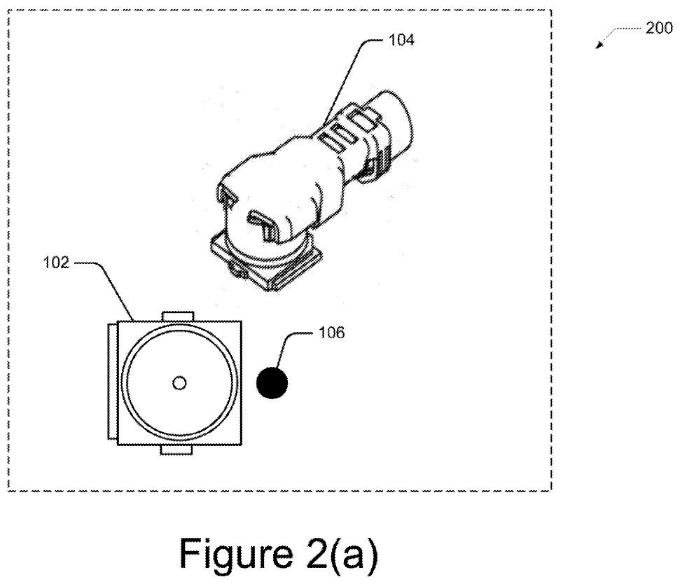

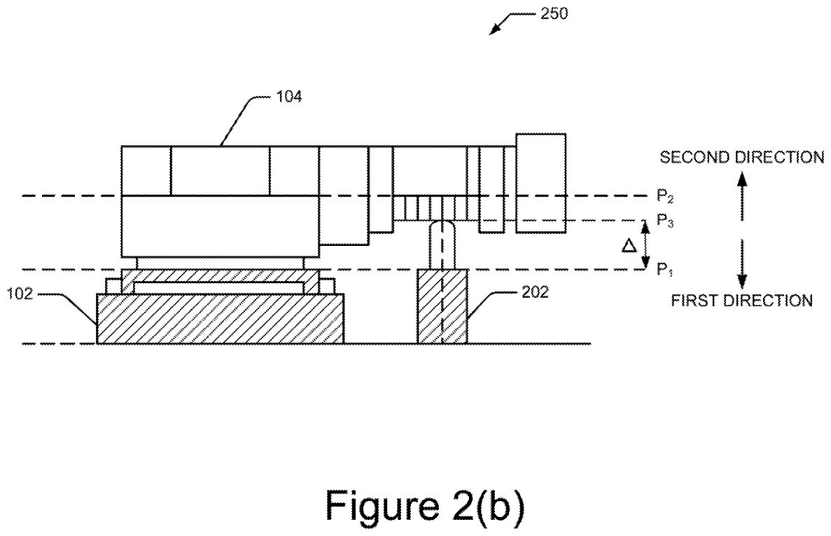

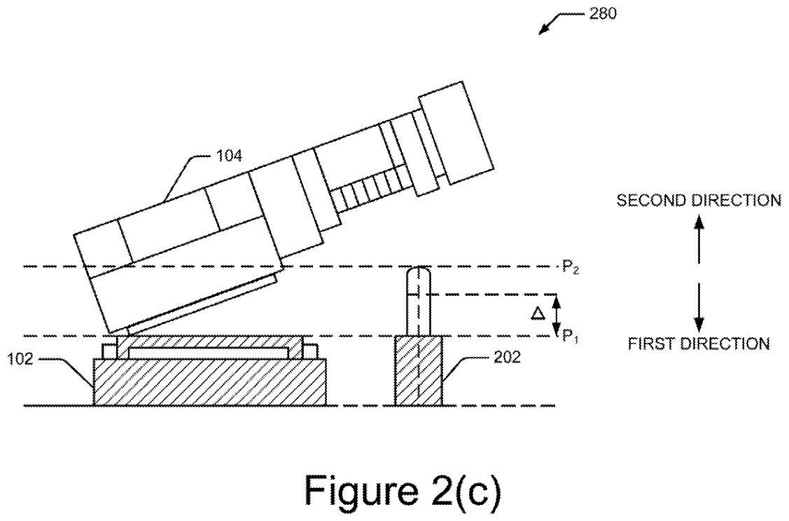

FIG. 2(a) illustrates a top-view of a connection assembly 200, in accordance with an example implementation of the present subject matter. The connection assembly 200 includes the connection interface 102 and the connector 104 electrically coupled to the connection interface 102. The contact detection assembly 106 may determine a state of a connection between the connection interface 102 and the connector 104 based on the position of the connector 104 relative to the connection interface 102.

In an example implementation of the present subject matter, the connector 104 may be coupled to the connection interface such that top of the connection interface 102 received bottom of the connector 104. The connection detection assembly 106, placed adjacent to the connection interface 102 may determine the state of the connection between the connection interface 102 and the connector 104. The implementation of the connection detection assembly 106 is further explained with refence to an example implementation in reference to FIGS. 2(b) and 2(c).

FIG. 2(b) and FIG. 2(c) illustrates side-views of the connection assembly 200, in accordance with example implementations of the present subject matter. In an example implementation of the present subject matter, the contact detection assembly 106 includes a plunger pin 202 to determine the position of the connector 104 relative to the connection interface 102 based on a position of the plunger pin 202.

Referring to FIG. 2(b), a connection assembly 250 is depicted indicating a connection between the connection interface 102 and the connector 104. The connection detection assembly 106 includes the plunger pin 202. The plunger pin 202 may move between a compressed position P₁ and an uncompressed position P₂. It would be noted that in between the compressed position P₁ and an uncompressed position P₂, the plunger pin 202 may move in the first and the second direction to different positions. For example, in idle situations when the connection interface 102 is not coupled to any connector 104 the plunger pin 202 may remain in the uncompressed position P₂. Further, the plunger pin 202 may be compressed in the first direction to move towards the completely compressed position P₁ during connection between the connection interface 102 and the connector 104.

In an example implementation of the present subject matter, while the connector 104 is connected to the connection interface 102, the plunger pin 202 is compressed to a position P₃ from the uncompressed position P₂. As described earlier, the plunger pin 202 may move in the first direction while being compressed by the connector 104, when the connector 104 is coupled to the connection interface 102. It would be noted that while the plunger pin 202 may get compressed by the connector 104 when the connection interface 102 and the connector 104 are coupled, the plunger pin 202 may get back to uncompressed in second direction and move towards the position P₂ when the connection interface 102 and the connector 104 is loose, or the connection interface 102 and the connector 104 are not coupled.

Thus, based on the position of the plunger pin 202, the contact detection assembly 106 may determine the state of the connection between the connector 104 and the connection interface 102.

In an example implementation of the present subject matter, the plunger pin 202 of contact detection assembly 106 may be coupled with a metal part (not shown) of the connector 104 when the connection interface 102 and the connector 104 are coupled. As discussed earlier, when the connection interface 102 and the connector 104 are coupled, the plunger pin 202 may be in a compressed position while coupled with the metal part (not shown) of the connector 104. In an example, the metal part of the connector 104 may be a ground terminal of the connector 104.

In an example, the plunger pin 202 may be a three-terminal device with a first terminal connected to a voltage source through a pull-up resistor. A second terminal of the plunger pin 202 may further be connected to a connection indicator formed on a printed circuit board (PCB) of the electronic device. In an example, the connection indicator may also be formed as a part of at least one of a Microcontroller unit (MCU), a central processing unit (CPU), and a basic input output system (BIOS) of the electronic device. Further, the plunger pin 202 may be coupled to the metal part of the connector 104 via a third terminal.

In operation, the presence of coupling between the connector 104 and a terminal of the plunger pin 202 may ground the terminal of the plunger pin 202. As a result, a connection between the voltage source and the connection indicator may move to an open state. The connection indicator, thus, remains turned off until there is any disruption in coupling between the plunger pin 202 and the metal part of the connector 104, Therefore, a turned off connection indicator may indicate that a coupling between the connection interface 102 and the connector 104 is working and the electronic component is in the working state.

In an example, the plunger pin 202 maintains the coupling with the metal part of the connector 104 while uncompressing in the second direction. The plunger pin 202 may expand to a threshold gap Δ between the connection interface 102 and the connector 104 to maintain the coupling with the metal part of the connector 104.

There may be a situation when the position of the connector 104 may change relative to the connection interface 102 in a way, such that, the gap between the connection interface 102 and the connector 104 may become larger than the threshold gap A. In such situation, the plunger pin 202 may move beyond the threshold gap A, to the uncompressed position P₂, as depicted in FIG. 2(c).

The change in the position of the plunger pin 202 disrupts the presence of coupling between the terminal of the plunger pin 202 and the metal part (not shown) of the connector 104. The disruption in the coupling between the third terminal of the plunger pin 202 and the metal part of the connector 104 establishes a connection between the voltage source and the connection indicator. As a result, the connection indicator may be turned on, indicating a disruption in coupling between the connection interface 102 and the connector 104. In the example, where the connection indicator is formed as the part of at least one of the MCU, BIOS, and CPU, the at least one of the MCU, BIOS, and CPU may monitor the state of the connection indicator. Based on the state of the connection indicator, the working state of the electronic components may be determined and the electronic device may be configured to operate using the electronic components in an active state.

Therefore, a turned on connection indicator may indicate that the coupling between the connection interface 102 and the connector 104 is not working and the electronic component is not in the working state.

While the determination of the state of connection between the connection interface 102 and the connector 104 has been explained with respect to the coupling between the plunger pin 202 and the metal part of the connector 104, it should be noted that the plunger pin 202 may also be coupled to other components of the connection assembly 200 for determination of the state of the connection between the connection interface 102 and the connector 104. For instance, the plunger pin 202 may be connected to a metal part of a coaxial cable connected to the connector 104.

Further, while the contact detection assembly 106 has been described to use the plunger pin 202 to determine the state of the connection between the connection interface 102 and the connector 104, it should not be construed as a limitation and other mechanisms may be utilized by the connection detection assembly to determine the state of connection between the connection interface 102 and the connector 104. For instance, the contact detection assembly 106 may detect the position of the connector 104 relative to the connection interface 102 using a proximity sensor. The proximity sensor may detect the gap between the connection interface 102 and the connector 104. Further, as described earlier, based on the gap between the connection interface 102 and the connector 104, the proximity sensor may determine the state of connection between the connection interface 102 and connector 104.

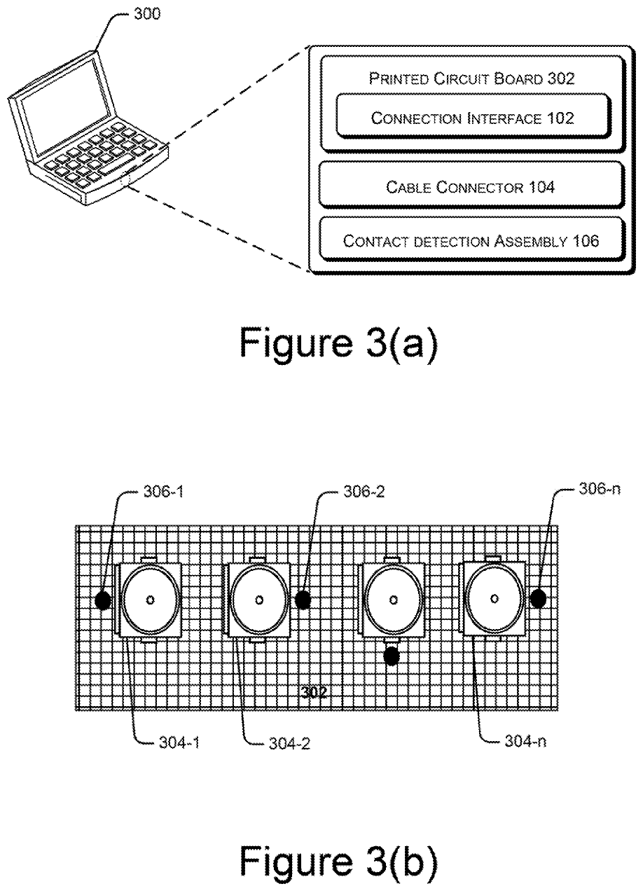

FIG. 3(a) and FIG. 3(b) illustrate an electronic device 300, in accordance with example implementations of the present subject matter. Examples of electronic device 300 may include, but not limited to, routers, laptop, desktop, personal digital assistant (PDA), and tablets. The electronic device 300 may have various electronic components that may perform various functions. For instance, the electronic device 300 may have a plurality of antennas for transmission and reception of wireless signals. Examples of the electronic components may further include, but not limited to, antennas, cameras, storage devices, integrated chips (ICs), resistors, capacitors, diodes, transistors, sand sensors.

The electronic device 300 may have a Printed Circuit Board (PCB) 302 that may facilitate the electronic device to be connected to the electronic components. To facilitate the connection, the PCB 302 may include the connection interface 102 to connect to a connector 104 of the electronic components. The connection interface 102 may be coupled to the PCB 302 in a number of ways. In an example, the connection interface 102 may be formed as a part of the PCB 302. In another example, the connection interface 102 may be assembled separately on the PCB 302.

The electronic device 300 may further include the contact detection assembly 106. The contact detection assembly 106 may be coupled to the electronic device 300 in a number of ways. In an example, the contact detection assembly 106 may be formed on the PCB 302. In another example, the contact detection assembly 106 may be assembled separately on the PCB 302. As discussed earlier, the contact detection assembly 106 may identify the state of a connection between the electronic device 300 and each of the electronic components. In an example, the contact detection assembly 106 may identify the state of the connection between the electronic device and each of the electronic components based on a position of the connector 104 relative to the connection interface 102.

In an illustrative example, the electronic device 300 may be a Multiple Input Multiple Output (MIMO) system. In an instance, the MIMO system may be a 4×4 MIMO system. That is, the MIMO system comprises four antennas for communication. To facilitate the coupling of the antennas to the MIMO system, the MIMO system may further comprise multiple connection interfaces. An arrangement of the connection interfaces to facilitate the coupling of the antennas to the MIMO system is illustrated in FIG. 3(b).

Referring to FIG. 3(b), connection interfaces 304-1, 304-2, . . . , 304-1 may be utilized to couple antennas to the MIMO system via four individual connectors (not shown). For the ease of reference, the connection interfaces 304-1, 304-2, . . . , 304-n has been collectively referred to as connection interface 304, hereinafter. The MIMO system may further comprise contact detection assemblies 306-1, 306-2, 306-n, corresponding to each of the connection interfaces 304. For the ease of reference, the contact detection assemblies 306-1, 306-2, . . . , 306-n has been collectively referred to as connection assembly 306, hereinafter.

As described earlier, each of the contact detection assembly 306 may detect the state of a connection between the respective connection interface 304 and a connector of an antenna from amongst the 4 MIMO. Based on the state of the connection between each of the connection interface 304 and the cable connector, the number of active antennas in the MIMO system may be determined. Accordingly, the active antennas may be configured for communication.

Further, as illustrated in FIG. 3(b), the contact detection assembly 306 may take multiple positions with respect to the connection interface 304 on the electronic device 300. The multiple positions of the contact detection assembly 106 may be determined based on varying mechanical designs of various electronic devices. That is, for various electronic devices, coaxial cables may have different routing directions. Thus, the contact detection assembly 106 may accordingly take different positions to detect the position of either the coaxial cable or the cable connector with respect to the connection interface 102.

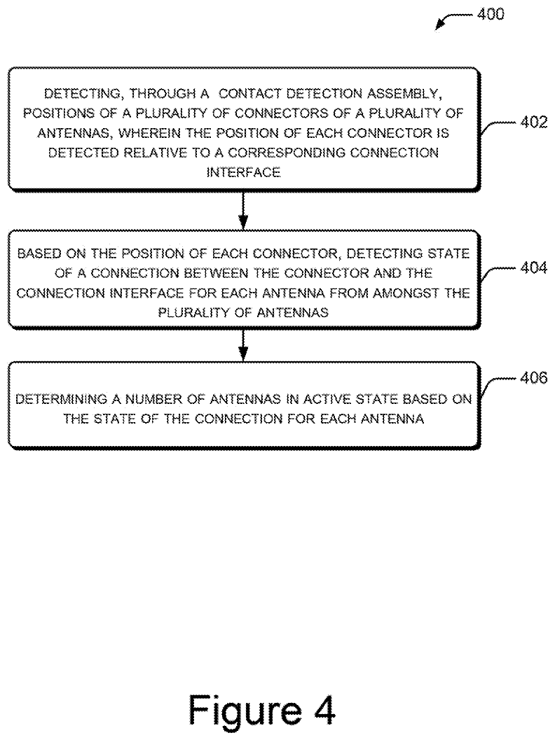

FIG. 4 illustrates a method 400 for detecting a working state of a plurality of antennas, in accordance with an example implementation of the present subject matter. Although the method 400 may be implemented in a variety of computing devices, but for the ease of explanation, the description of the exemplary methods 400 is provided in reference to the above-described electronic device 300. The order in which the method 400 is described is not intended to be construed as a limitation, and any number of the described method blocks may be combined in any order to implement the method 400, or an alternative method.

It may be understood that blocks of the method 400 may be performed in the electronic device 300. The blocks of the method 400 may be executed based on instructions stored in a non-transitory computer-readable medium, as will be readily understood. The non-transitory computer-readable medium may include, for example, digital memories, magnetic storage media, such as magnetic disks and magnetic tapes, hard drives, or optically readable digital data storage media.

At block 402, positions of a plurality of connectors of a plurality of antennas may be detected. The position of the plurality of antennas may be detected relative to a corresponding connection interface. In an example, each connector out of the plurality of connectors and each connection interface out of the plurality of the connection interfaces corresponds to a connector 104 and connection interface 102 respectively of the electronic device 300. Further, the positions of the plurality of connectors of the plurality of antennas are detected through a contact detection assembly 106 of the electronic device 300.

At block 404, based on the position of each connector, a state of a connection between the connection interface and connector for each antenna from amongst the plurality of antennas is detected. in an example, based on the position of each connector, the contact detection assembly 106 detects the state of connection between the connection interface and the connector for each antenna to be one of active and inactive. Specifically, the contact detection assembly 106 detects a gap between the connection interface and the connector for each of the plurality of antennas to detect the state of the connection. If the gap between the connection interface and the connector for each of the plurality of antennas is equal to or above a threshold gap, the state of the connection is active. Otherwise, the state of the connection is inactive, Further, based on the state of the connection between the connection interface and the connector for each of the plurality of antennas, a mapping table may be created. The mapping table may identify each antenna from the plurality of antennas using a unique ID. The mapping table may further include the state of the connection between the connection interface and the connector for each antenna with the unique ID of each antenna.

At step 406, based on the state of the connection for each antenna, a number of antennas out of the plurality of antennas may be determined to be in an active state. In an example, the state of the connection for each antenna is determined from the mapping table. Based on the state of the connection for each antenna, an electronic device is configured to communicate using at least one antennas in the active state. For instance, in a 8×8 Multiple Input Multiple Output (MIMO) system, if 4 antennas are found to be in the active state, the 8×8 MIMO system may be configured to use the antennas in the active state and operate as 4×4 MIMO system. Further, there may be a situation where the 8x8 MIMO system may be configured to operate as 4×4 MIMO. That is, the 8×8 MIMO system may have 4 antennas configured for communication. In such situation, the working state of the 4 antennas may be determined. Based on the antennas in the active state, the 8×8 MIMO system may be configured to operate in various configurations.

Although implementations of the present subject matter have been described in language specific to methods and/or structural features, it is to be understood that the present subject matter is not limited to the specific methods or features described. Rather, the methods and specific features are disclosed and explained as example implementations of the present subject matter.

We claim:

1. A connection assembly comprising;
a connection interface to couple the connection assembly to an antenna of an electronic device via a connector; and
a contact detection assembly to detect a state of a connection between the connector and the connection interface, wherein the state of the connection is determined based on a position of the connector relative to the connection interface.

2. The connection assembly as claimed in claim 1, wherein the contact detection assembly comprises a detection pin to detect the state of the connection between the connector and the connection interface.

3. The connection assembly as claimed in claim 1, wherein the contact detection assembly detects the state of the connection based on a gap between the connector and the connection interface.

4. The connection assembly as claimed in claim 3, wherein the contact detection assembly detects the state as active on determination of the gap to be below a threshold.

5. The connection assembly as claimed in claim 4, wherein the contact detection assembly detects the state as inactive on determination of the gap to be above the threshold.

6. An electronic device comprising:
a printed circuit board (PCB) comprising a connection interface to couple to a cable connector of an electronic component; and
a contact detection assembly to:
detect a position of the cable connector relative to the connection interface; and
determine a state of connection between the cable connector and the connection interface based on the position of the cable connector.

7. The electronic device as claimed in claim 6, wherein a working state of the electronic component is determined based on the state of connection between the cable connector and the connection interface.

8. The electronic device as claimed in claim 6, wherein the cable connector is a Radio Frequency (RF) connector.

9. The electronic device as claimed in claim 8, wherein the cable connector is at least one of a Bayonet Neill—Concelman (BNC) connector, Sub Miniature Version A (SMA) connector, Sub Miniature Version B (SMB) connector, Threaded Neill—Concelman (TNC) connector, and micro coaxial connector (MCX) connector.

10. The electronic device as claimed in claim 6, wherein the electronic component is coupled to the connection interface through a coaxial cable.

11. The electronic device as claimed in claim 6, wherein the contact detection assembly comprises a detection pin, and wherein the detection pin is a plunger pin.

12. The electronic device as claimed in claim 11, wherein the detection pin contacts a metal part of the cable connector.

13. A method comprising:
detecting, through a contact detection assembly, positions of a plurality of connectors of a plurality of antennas, wherein the position of each connector is detected relative to a corresponding connection interface;
based on the position of each connector, detecting a state of a connection between the connector and the connection interface for each antenna from amongst the plurality of antennas; and
determining a number of antennas in an active state based on the state of the connection for each antenna.

14. The method as claimed in claim 13, further comprising determining another number of antennas in an inactive state based on the state of the connection for each antenna.

15. The method as claimed in claim 13, further comprising configuring an electronic device to communicate based on the number of antennas in the active state.
